(19) United States
(12) Patent Application Publication
(10) Pub. No.: US 2003/0081395 A1
(43) Pub. Date: May 1, 2003

(54) Portable electronic equipment

(75) Inventor: Masayuki Katagiri, Nara-ken (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha

(21) Appl. No.: 10/280,098

(22) Filed: Oct. 25, 2002

Related U.S. Application Data
(63) Continuation-in-part of application No. 10/061,325, filed on Feb. 4, 2002.
Application No. 10/061,325 is a continuation of application No. 09/594,603, filed on Jun. 15, 2000, now Pat. No. 6,366,459.

(30) Foreign Application Priority Data
Jun. 15, 1999 (JP) 11-168565
Jun. 6, 2002 (JP) 2002-165930

(51) Int. Cl. H05K 7/14; H05K 7/18

(52) U.S. Cl. 361/800

(57) ABSTRACT

In portable electronic equipment, a liquid crystal display panel is mounted on the front face side of a casing of the display section, and a thin type battery section is removably fitted to a fitting portion on the rear face side of the casing. The thin type battery section is fixed to a high-strength support plate with flat portions of thin type batteries in close contact therewith. The thin type batteries are put into close contact with the thin high-strength support plate to back up the support plate. Thus, the support plate hardly flexes or dents, and the thin type batteries are free from occurrence of bending deformation.

This application is a Continuation-In-Part of application Ser. No. 10/061,325 filed Feb. 4, 2002.

### BACKGROUND OF THE INVENTION

The present invention relates to portable information equipment having a main body portion and a display portion foldably connected so as to be opened and closed.

Portable information equipment such as so-called notebook personal computers and word processors incorporate a chargeable internal battery so as to be able to use the equipment at a location where an alternating current power supply is not available. FIG. 4 shows a constitution of generally known portable information equipment 1. A portable information equipment 1 of such a type includes a main body portion 2 and a display portion 3 hinged each other, and usually an internal battery 4A is disposed at one corner of the main body portion 2.

In any portable information equipment 1 of this type, for the purpose of enhancing the portability of the equipment 1, while thickness reduction and weight reduction of the main body portion 2 and display portion 3 are required, as another important problem to be solved, there is an ardent demand for increasing a capacity of the internal battery 4A and extending a battery life thereof. However, in order to increase the capacity of the internal battery 4A, inevitably it is necessary to enlarge the outer shape of the internal battery 4A; therefore, the capacity of the internal battery 4A is set in consideration of the balance relative to a cabinet 21 of the main body portion 2 in which the internal battery 4A is disposed.

In the case that the battery capacity is insufficient with the internal battery 4A alone, an extension battery 4B as shown in FIG. 5 is externally attached to the main body portion 2 in order to supplement the resulting battery capacity shortage. However, external attachment of the extension battery 4B is considerably detrimental to the portability of the portable information equipment 1.

For a display unit 5 used in the display portion 3 of the portable information equipment 1, a liquid crystal display is generally employed. In the past, transmission type liquid crystal displays with backlight were in a main stream, but in recent years, reflection type liquid crystal displays have also been employed because the reflection type display can provide a clear color display without using any backlight.

FIG. 6 is a fragmentary sectional view showing an edge part of the display portion 3 using a transmission type liquid crystal display 5. The transmission type liquid crystal display 5 comprises a transmission type liquid crystal unit 5A and a backlight unit 5B. The transmission type liquid crystal unit 5A has a laminate of a glass layer 51, a polarizer layer 52, and the like with a liquid crystal layer sandwiched therebetween. The backlight unit 5B is disposed behind the transmission type liquid crystal unit 5A and has a light guide plate 53, a backlight 54, and the like. These units are incorporated into a cabinet 31 of the display portion 3. The thickness of the backlight unit 5B is approximately 3 mm or so.

Whilst, a reflection type liquid crystal display comprises a reflection type liquid crystal unit formed in about the same thickness as that of the transmission type liquid crystal unit 5A so that thickness reduction and weight reduction can be realized to an extent corresponding to omission of the backlight unit 5B, compared with the transmission type liquid crystal display 5. Furthermore, display can be performed through utilization of reflected light from external light and not through illumination by the backlight 54, and this provides for an advantage of substantial reduction of electric power consumption.

However, there are commercial demands for both portable information equipment 1 using a transmission type liquid crystal display 5 and portable information equipment 1 using a reflection type liquid crystal display. As such, manufacturers of portable information equipment 1 are required to prepare and supply both types of products. Therefore, for portable information equipment 1 using reflection type liquid crystal display, despite the fact that the use of reflection type liquid crystal display enables thickness reduction of display portion 3 in relation to portable information equipment 1 using transmission type liquid crystal display 5, manufacturers are still using the cabinet 31 common to both types of display portion 3 of portable information equipment 1 due to cost reduction of development and manufacturing.

### SUMMARY OF THE INVENTION

An object of the invention is to provide portable electronic equipment which allows easy replacement of thin type batteries without impairing strength of its display section.

In order to achieve the above object, the present invention provides portable electronic equipment having a display section comprising:

a casing;

a flat display panel mounted on the casing; and

a thin type battery section having a flat thin type battery and removably fitted to the casing so as to be positioned on a rear face side of the flat display panel.

It is noted here that the terms, “thin type battery,” refer to a battery having a thickness of 2 mm to 6 mm and a flat-portion area of 10 cm² or more.

With this arrangement, the thin type battery can be replaced with another easily by removing from the casing the thin type battery section having the thin type battery.

Further, since the thin type battery section is removably fitted to the casing, the display section can be enhanced in strength by virtue of the combination of the casing and the thin type battery section.

In one embodiment, the thin type battery section has a support plate forming the rear face of the display section, and the thin type battery is fitted to the support plate.

The thin type battery may be attached to the support plate either removably or unremovably.

In this embodiment, in the case where the thin type battery is attached to the support plate removably, the thin type battery section is first removed from the casing and thereafter the run-out thin type battery is removed from the support plate. Then, a new thin type battery is attached to the support plate, and the thin type battery section is attached to the casing. In this way, the support plate can be reused by easily replacing only the run-out thin type battery. Meanwhile, in the case where the thin type battery is attached to the support plate unremovably, the thin type battery is replaced together with the support plate. This replacement is conducted by removing the thin type battery section having the run-out thin type battery from the casing, and then by attaching to the casing a new thin type battery section having a new thin type battery. In this way, the thin type battery can be replaced with great ease.

Further, the display section can be enhanced in strength by virtue of the combination of the casing forming the rear face of the display section and the casing.

In one embodiment, the flat portion of the thin type battery is put into close contact with the support plate to back up the support plate.

In this embodiment, the flat portion of the thin type battery is put into close contact with the support plate to back up the support plate so that the support plate is reinforced. Thereby, the support plate, even if thin, does not incur flexure or detents, so that the rear face of the display section has enough strength. Accordingly, the support plate can be made small in thickness, and so the display section can be made thin in thickness and light in weight. Further, since the flat portion of the thin type battery is fixed in close contact with the high-strength support plate, the thin type battery, even if relatively low in strength, does not incur bending deformation or the like, eliminating the possibility of damaging the reliability of electrical connection between the power supply line and the terminals, or the like.

In one embodiment, the support plate is generally rectangular shaped, and a flat portion of the thin type battery and a control board having a circuit for control use are fitted in close contact to the support plate so as to occupy a generally rectangular region inner than an outer edge of the support plate.

In this embodiment, since the flat portion of the thin type battery and the control board are put in close contact with the support plate, the support plate can be reinforced to enhance the display section in strength. Also, the thin type battery and the control board, even if relatively low in strength, are free from occurrence of bending deformation or the like, eliminating the possibility of damaging the reliability of electrical connection between the power supply line and the terminals.

In one embodiment, a singularity or plurality of the thin type batteries are disposed on each one side of the control board, and positive terminals and negative terminals of the individual thin type batteries are protrudent toward the control board and connected to a power supply line provided on the control board.

In this embodiment, since the positive terminals and negative terminals of the thin type batteries disposed on each one side of the control board are protrudent toward the control board and connected to a power supply line provided on the control board, that is, since the positive terminals and negative terminals of the thin type batteries located on both sides of the control board are connected directly to the power supply line provided on the centrally located control board, the power supply line can be made shorter in length, and further the thin type batteries and the control board can be mounted compact on the support plate.

In one embodiment, the casing has a fitting portion to which an edge portion of the thin type battery section is to be removably fitted in a specified direction.

In this embodiment, since the edge portion of the thin type battery section is removably fitted to the fitting portion of the casing, the thin type battery section can be fitted to and removed from the casing with ease. Accordingly, the replacement of the thin type batteries can be achieved easily.

In one embodiment, a singularity or plurality of the thin type batteries are attached to the support plate so that an edge portion of the thin type battery section is formed into a step-like shape by the support plate and the thin type batteries, and the casing has a fitting portion to which the edge portion of the thin type battery section is to be removably fitted, and the fitting portion comprises a support-plate fitting portion to which the edge portion of the support plate is fitted, and a thin-type battery accommodating portion for accommodating the thin type batteries.

In this embodiment, the step-like edge portion of the thin type battery section is fitted to the fitting portion of the casing in a specified direction. Therefore, the thin type battery section is prevented from reverse-directed insertion, so that contact points of the thin type battery section side and the casing side can be reliably connected. The specified direction is defined as, for example, a direction extending along the support plate forming the rear face of the display section, or a direction perpendicular to the rear face, or both directions of the direction along the support plate and the direction perpendicular to the rear face.

In one embodiment, the support plate is generally rectangular shaped with at least a pair of its opposing edge portions formed into a step-like shape, and has a recess at a center portion of the support plate, and the thin type battery is attached to the recess with the flat portion of the thin type battery in close contact therewith, and the casing has a fitting portion to which a top of the edge portion of the support plate is removably fitted.

In this embodiment, the thin type battery section can be made small in thickness and so the display section can be small in thickness since the flat portions of the thin type batteries are put into close contact with the recess located at the center of the support plate. Also, since the top of the stepped edge portions of the generally rectangular-shaped support plate is fitted to the fitting portion of the casing, the fitting portion of the casing can be made thinner in correspondence to the thickness of the top of the stepped edge portion, and so the casing as well as the display section can be made thinner.

In one embodiment, the fitting portion has a guide groove for allowing the support plate forming the rear face of the display section to slide along the rear face.

In this embodiment, the guide groove of the fitting portion allows the support plate forming the rear face of the display section to slide along the rear face. Accordingly, the support plate can be securely attached to the guide groove, and thereby retained. Thus, the support plate as well as the thin type battery section are unlikely to drop from the casing.

In one embodiment, a detent mechanism is provided in the casing and the thin type battery section, so that the casing and the thin type battery section are retainable by the detent mechanism.

In this embodiment, the detent mechanism retains the thin type battery section to the casing. Accordingly, the thin type battery section can be prevented from loosening away from the casing.

In one embodiment, the casing is a frame structure having an outer frame and at least one of a beam portion and a brace coupled to the outer frame.

In this embodiment, the casing has an outer frame, and at least one of a beam portion and a brace coupled to the outer frame. Accordingly, the casing has enough strength even when a very large force is applied to the casing upon opening or closing of the casing in the state that the heavyweight thin type battery section is set, or even when the thin type battery section is removed from the casing.

In one embodiment, the portable electronic equipment further comprises: a body section including an input section and a control section having an information processing function, wherein the display section includes a radio receiving section while the body section includes a radio transmitting section, and wherein the radio receiving section of the display section receives data transmitted by radio from the radio transmitting section of the body section so as to display the data on the flat display panel.

In this embodiment, data can be transmitted wirelessly from the radio transmitting section of the body section to the radio receiving section of the display section, and displayed on the flat display panel. Also, since the capacity of batteries can be increased by setting multiple or larger-area thin type batteries to the thin type battery section, the flat display panel and the radio receiving section can be driven for a prolonged time even with the radio receiving section provided in the display section.

A radio transmitting/receiving section may be used instead of the radio receiving section and the radio transmitting section.

In one embodiment, the flat display panel serves also as an input section, a control section having an information processing function is provided in the casing, and the flat display panel and the thin type battery section are generally equal in area to each other.

In this embodiment, the display section has an input function, a display function and an information processing function. Moreover, the flat display panel and the thin type battery section occupy front face and rear face of the display section, respectively. Accordingly, so-called card-type or sheet-type portable information equipment which allows easy replacement of batteries and which is thin, flat shaped can be obtained. Further, since the flat display panel and the thin type battery section are generally equal in area to each other, the capacity of batteries can be increased, allowing longer-period use.

Also, the present invention also provides a thin type battery assembly comprising:

a support plate; and

a singularity or plurality of thin type batteries attached to the support plate so as to be positioned in a region which is inner by a specified size than an outer edge of the support plate,

wherein the edge portion of the support plate and the thin type batteries form a step-like shape.

It is noted that the shape of the support plate may be not only rectangular but also circular or elliptical or other shapes.

In the thin type battery assembly of this constitution, since a singularity or plurality of thin type batteries are attached to the support plate so as to be positioned in a region which is inner by a specified size than an outer edge of the support plate, the support plate can be reinforced so as to be reduced in thickness, allowing the thin type battery assembly to be provided as a thin type. Also, since the thin type batteries are attached to the high-strength support plate, the thin type batteries, even if relatively low in strength, are prevented from bending deformation or the like, thus eliminating the possibility of damaging the reliability of electrical connection between the power supply line and the terminals.

Further, in this thin type battery assembly, since the edge portion of the support plate and the thin type batteries form a step-like shape, fitting the stepped portion to the casing allows the thin type battery assembly to be attached to and removed from the casing in one way or in two ways, thus facilitating the fitting and removal. Furthermore, using this thin type battery assembly allows easy replacement of batteries for the portable electronic equipment.

The present invention also provides a thin type battery assembly comprising:

a generally rectangular-shaped support plate of which at least a pair of opposing edge portions are formed into a step-like shape, and which has a recess at a center portion; and

a thin type battery attached to the recess of the support plate with its flat portion in close contact therewith.

In the thin type battery assembly of this constitution, since the thin type battery is attached with its flat portion in close contact with the recess of the support plate, the support plate can be reinforced and therefore thinned. This allows the thin type battery assembly to be provided as a thin type one. Further, since the flat portion of the thin type battery is fixed in close contact with the high-strength support plate, the thin type battery, even if relatively low in strength, is free from occurrence of bending deformation or the like, thus eliminating the possibility of damaging the reliability of electrical connection between the power supply line and the terminals. Furthermore, since opposing edge portions of the generally rectangular-shaped support plate are formed into a step-like shape, fitting the tops of these edge portions to the guide groove of the casing allows the guide groove to be narrowed in width, so that the casing can be made small in thickness. Furthermore, using this thin type battery assembly allows easy replacement of batteries for the portable electronic equipment.

In one embodiment, a control board having a circuit for control use is attached to the support plate, and a singularity or plurality of the thin type batteries are disposed on each one side of the control board, and a positive terminal and a negative terminal of each of the thin type batteries are protrudent toward the control board and connected to a power supply line provided on the control board.

In this embodiment, since the positive terminals and negative terminals of the thin type batteries located on both sides of the control board are connected directly to the power supply line provided on the centrally located control board, the power supply line can be made shorter in length, and further the thin type batteries and the control board can be mounted compact on the support plate.

In one embodiment, the thin type batteries and the control board are coated with a protective film, so that the thin type batteries and the control board are protected from moisture, dust and the like.

It is noted that the terms, “portable electronic equipment,” herein refer to portable information equipment such as notebook personal computers, PDAs (Personal Digital Assistants), e-mail terminals and electronic dictionaries, or portable AV (Audio/Visual) equipment such as personal DVD (Digital Versatile Disc) equipment and video cameras, or portable communication equipment such as cellular phones, or the like.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a perspective view showing a schematic construction of a portable information equipment of the present invention;

FIG. 2 is a schematic view in section showing a vicinity of a frame of a display portion of the portable information equipment of the present invention;

FIG. 3 is an explanatory view showing a top plan construction of an interior of the display portion of the portable information equipment of the present invention;

FIG. 4 is a perspective view showing a schematic construction of a conventional prior art portable information equipment;

FIG. 5 is a perspective view showing the portable information equipment shown in FIG. 4 as fitted with an extension battery; and

FIG. 6 is a schematic sectional view showing an edge part of a display portion in which a transmission type liquid crystal display is employed.

FIG. 7 is a perspective view of portable information equipment according to a first embodiment of the present invention;

FIG. 8 is a perspective view of a thin type battery section of the portable information equipment according to the first embodiment;

FIG. 9 is a perspective view of a casing of the portable information equipment according to the first embodiment;

FIG. 10 is a perspective view of portable information equipment according to a second embodiment of the present invention;

FIG. 11 is a perspective view of a thin type battery section of the portable information equipment according to the second embodiment;

FIG. 12 is a perspective view of personal DVD equipment according to a third embodiment of the present invention;

FIG. 13 is a perspective view of a system integrated device according to a fourth embodiment of the present invention; and

FIG. 14 is a perspective view of portable electronic equipment according to a fifth embodiment of the present invention.

### DETAILED DESCRIPTION OF THE PREFERRED EMBODIMENTS

Hereinbelow, the present invention is described in detail by way of embodiments thereof illustrated in the accompanying drawings.

In the following description, with respect to portions and components similar in function to those of the aforesaid conventional portable information equipment 1, common designations and reference numerals are used.

FIG. 1 shows a schematic construction of portable information equipment 10 of the invention. The portable information equipment 10 comprises a main body portion 20 and a display portion 30. When the portable information equipment 10 is not used or is carried, the main body portion 20 and the display portion 30 is closed into unity. When the portable information equipment 10 is used, the main body portion 20 and the display portion 30 are opened to each other to operate the portable information equipment 10 using a keyboard 22 disposed in the main body portion 20. A chargeable first internal battery 4A, together with main board 23 including processing/memory units and the like, is housed in a cabinet 21 of the main body portion 20.

For the display portion 30 of the portable information equipment 10, a reflection type liquid crystal display 6 is used as a display unit. The reflection type liquid crystal display 6 is incorporated into a cabinet 31. The cabinet 31 can be also used for the aforesaid cabinet 31 which defines the display portion 3 of the portable information equipment 1 employing the liquid crystal display 5 with backlight shown in FIG. 6.

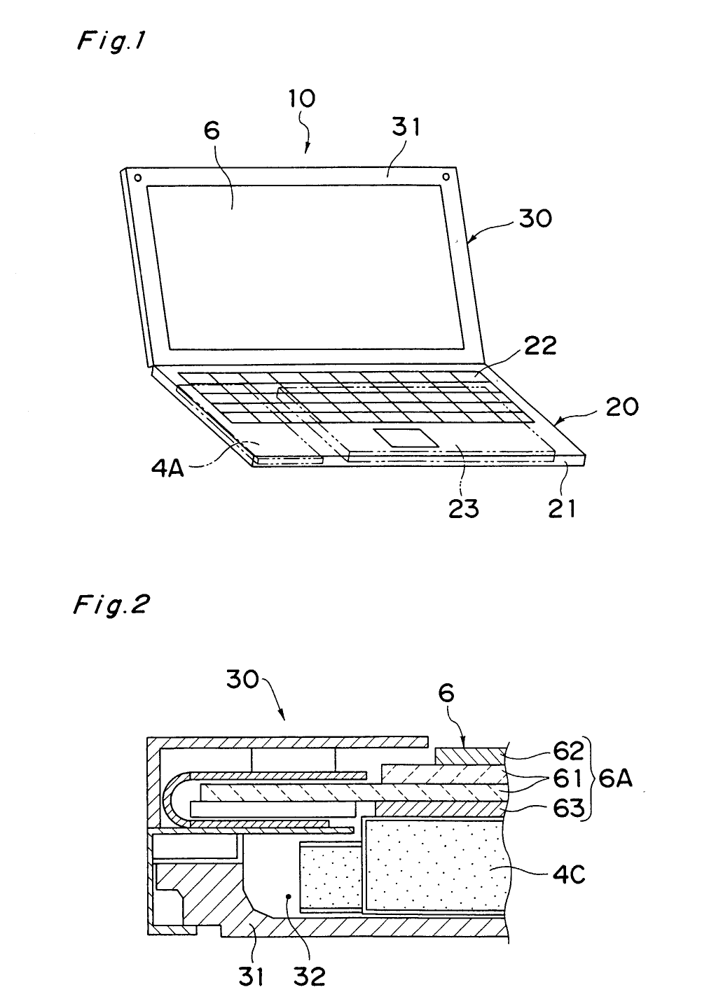

FIG. 2 is a sectional view showing a part of the structure of the display portion 30. The reflection type liquid crystal display 6 comprises a reflection type liquid crystal unit 6A which is formed in about the same thickness as that of the aforesaid liquid crystal unit 5A of the liquid crystal display 5 with backlight. The reflection type liquid crystal unit 6A comprises glasses 61 stacked with a liquid crystal layer held therebetween, polarizer 62, reflector 63 and the like. Accordingly, between the back surface of the reflection type liquid crystal unit 6A and the inner surface of the cabinet 31, there is formed a battery housing space 32 having a thickness of about 3 mm corresponding to the thickness of the backlight unit 5B of the liquid crystal display 5 with backlight shown in FIG. 6. A second internal battery 4C formed in thin plate shape is housed in the battery housing space 32.

In this way, by utilizing a cabinet 31 for common use with the portable information equipment 1 using the liquid crystal display 5 with backlight which requires the backlight and the portable information equipment 10 using a reflection type liquid crystal display 6 which does not require the use of backlight, it is possible to secure a battery housing space 32 in the display portion 30 for accommodating the second internal battery 4C. Thus, the capacity of the internal battery can be increased and, therefore, any externally attached extension battery is not necessary. Electric power requirement of the reflection type liquid crystal display 6 is far much smaller than that of the liquid crystal display 5 with backlight. Therefore, the useful life of battery is further extended and the utility of the portable information equipment 10 is substantially enhanced. Furthermore, the cabinet 31 of the display portion 30 and the associated components are commonized between the portable information equipment 10 using the reflection type liquid crystal display 6 and the portable information equipment 1 using the liquid crystal display 5 with backlight, whereby cost involved in assembling and manufacturing of the portable information equipment 10 can be curtailed.

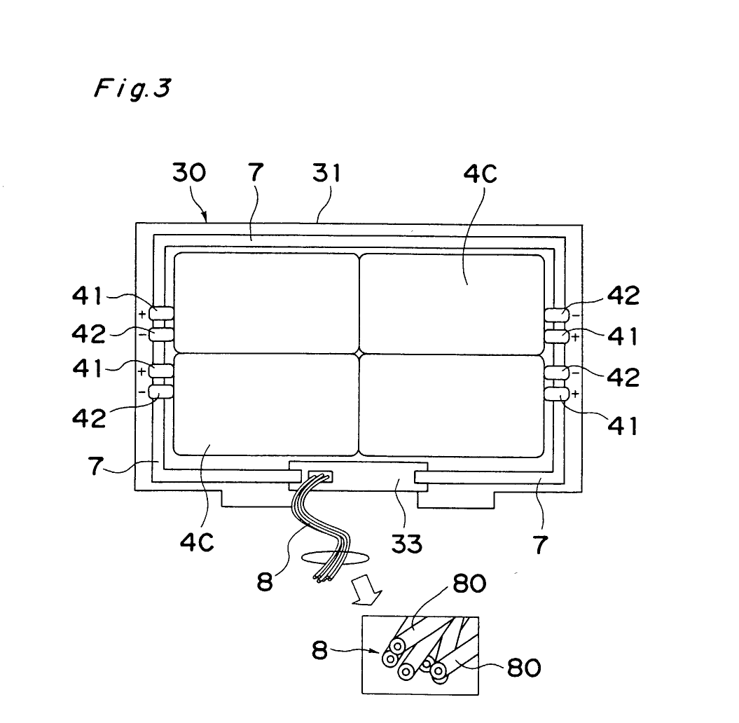

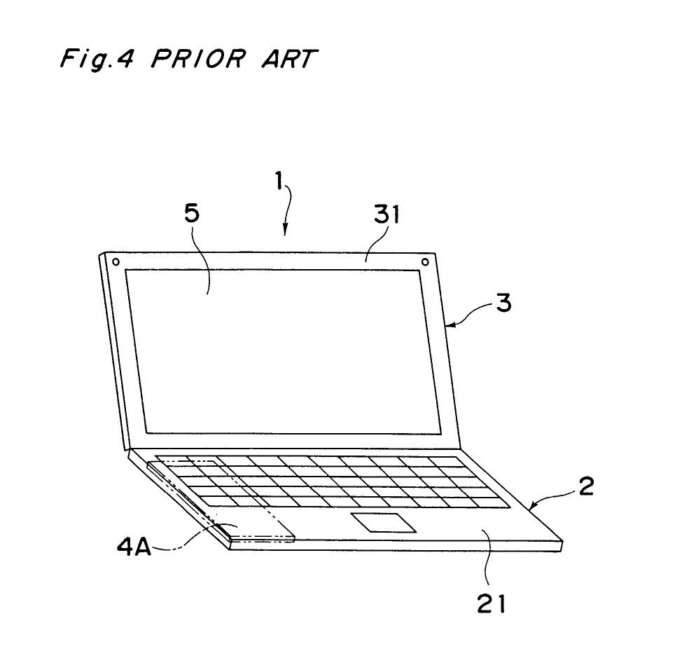

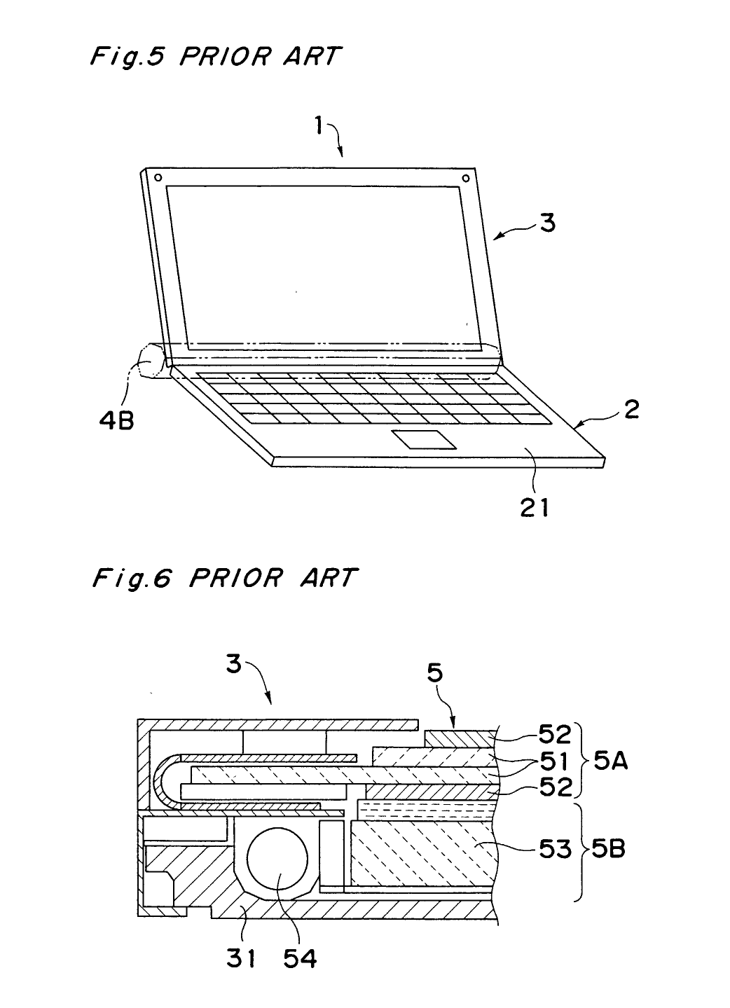

FIG. 3 shows a top plan view of the inside of the display portion 30 in the portable information equipment 10 of the above described arrangement. For example, in the case of a portable information equipment 10 having a 11.3 inch reflection type liquid crystal display 6 incorporated in the display portion 30, the external size of the display portion 30 is about 264 mm (in width)×about 207 mm (in length), and the size of display screen of the reflection type liquid crystal display 6 is about 230 mm (in width)×about 173 mm (in length). The size of a battery housing space 32 formed behind the reflection type liquid crystal display 6 is a few mm larger than the display screen in both width and length.

In this embodiment, a lithium polymer battery is used as a second internal battery 4C housed in the battery housing space 32. For example, one package of the lithium polymer battery 4C has a size of 114 mm (in length)×88.5 mm (in width)×3 mm (in thickness), four lithium polymer batteries 4C being arranged in the battery housing space 32. The package of the lithium polymer battery 4C has a positive terminal 41 and a negative terminal 42 both of which are connected to a battery control board 33 through flat type cables 7. For connecting the plural lithium polymer batteries 4C, several combinations in series and/or parallel is conceivable, but the combinations are not particularly defined in the present invention.

The battery control board 33 is similar in size to an inverter board (not shown) incorporated in the liquid crystal display 5 with backlight for lightening the backlight 54. Therefore, the battery control board 33 can be incorporated into the cabinet 31 without difficulty in the case where the cabinet 31 of the display portion 30 using the reflection type liquid crystal display 6 is common with the cabinet 31 of the display portion 3 using the liquid crystal display 5 with backlight.

FPC (flexible printed circuit) and FFC (flexible flat cable) are suitable for the flat cable 7. The FPC or FFC flat cable 7 is as thin as about 0.5 mm and has high flexibility, so that the FPC or FFC flat cable 7 can be easily incorporated in the cabinet 31 of the display portion 30 having limitations in thickness. Further, resistance of the FPC or FFC flat cable 7 is small, and therefore it is possible to flow a large current by widening the width of the flat cable 7.

The display portion 30 is connected to the main body portion 20 so as to be openable and closable with hinges (not shown). Therefore, in order to supply power from the second internal battery 4C housed in display portion 30 to the main body portion 20, a power supply cable 8 capable of feeding a large current is required. In the present embodiment, a power supply cable 8 consisting of plural independent slender electric wires 80 bundled together is used. Such a bundle of the electric wires 80 are connected at their ends to the battery control board 33 incorporated in the display portion 30. In the case where wires having a large diameter are used for the power supply cable 8, wire break or wire twist may occur in the course of repetitive opening/closing operations of the display portion 30. However, when the wires 80 are slender, possibility of wire break or wire twist can be minimized. Specifically, the thickness of the slender electric wire 80 is preferably is more slender than AWG (American Wire Gauge) #30.

As above described, according to the present invention, it is possible to incorporate a thin-plate second internal battery 4C into the display portion 30, by using the display unit 6 which requires no backlight in the display portion 30 to take advantage of the resulting thickness reduction, so as to increase the capacity and utility of the internal battery. Further, by using the cabinet 31 in common for the display portion 30 with no backlight and for the display portion 3 with the backlight 54, it is possible to reduce the costs involved in fabrication and assembly of the cabinet 31 and associated parts.

The display portion 30 is not particularly limited to the aforesaid reflection type liquid crystal display 6. Other display units such as EL (electro-luminescence) display, plasma display and field effect display may be used as well.

The aforesaid lithium polymer battery 4C is particularly suitable for the second internal battery 4C, but other thin-type batteries adaptable for capacity increase may be used. Further, in case that the performance of the second internal battery 4C has been exceedingly improved to sufficiently secure a necessary battery with the second internal battery 4C alone, the first battery 4A to be housed in the main body portion 20 can be omitted.

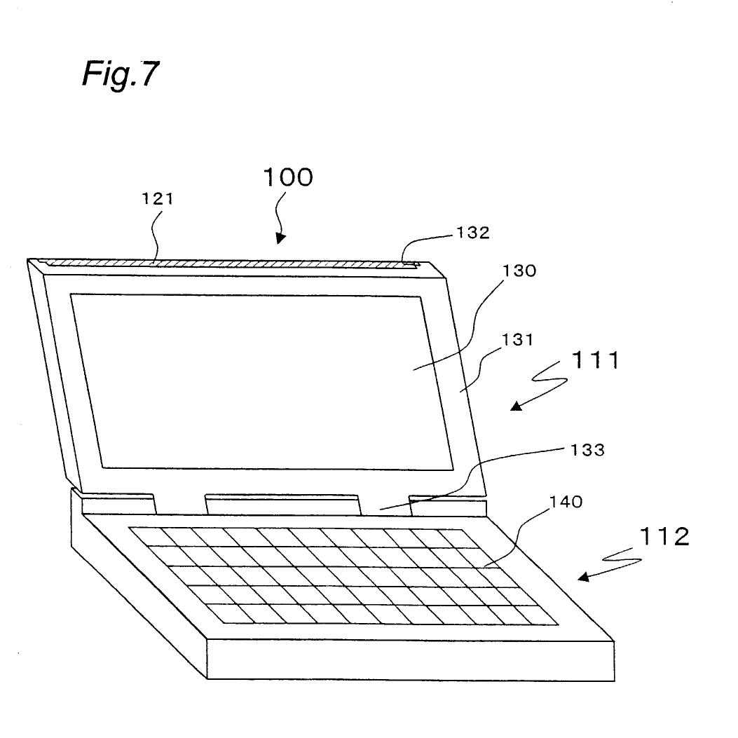

Portable information equipment as portable electronic equipment of a first embodiment of the present invention is, for example, a notebook personal computer, personal digital assistant, e-mail terminal device, electronic dictionary or the like. As shown in FIG. 7, a portable information equipment 100 is composed of a display section 111 and a body section 112, where the display section 111 is openably and closably attached to the body section 112 with a hinge portion 133. The body section 112 has a keyboard 140 and a motherboard (not shown). On the other hand, the display section 111 is composed of an LCD (Liquid Crystal Display) panel 130 as an example of flat display panels, a casing 131 and a thin type battery section 121. The LCD panel 130 is so attached to the casing 131 as to be placed on the front face side thereof. Moreover, the thin type battery section 121 is so attached as to be placed on the rear side of the LCD panel 130. The thin type battery section 121 is removably fitted to fitting portions 132 provided in the casing 131. The thin type battery section 121, when fitted to the fitting portions 132 of the casing 131, forms a rear part of the display section 111.

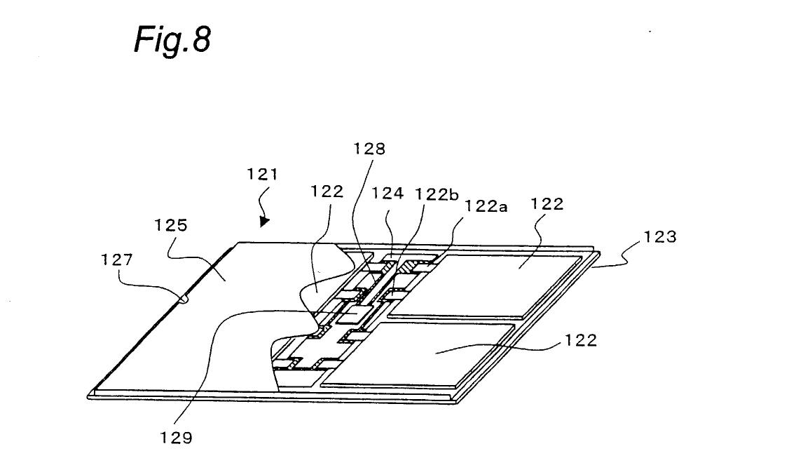

The thin type battery section 121, as shown in FIG. 8, is composed of a rectangular support plate 123, four thin type batteries 122, 122, 122, 122 on the support plate 123, a slender rectangular control board 124 on the support plate 123, and a protective film 125 made of resin. The thin type battery section 121 supplies electric power to the LCD panel 130 and the body section 112. The support plate 123 is made from a material having high strength even though thin, such as magnesium, aluminum, titanium or an alloy containing at least one among the above metals or an engineering plastic or the like. The support plate 123 forms most part of the rear side of the display section 111 shows in FIG. 7. That is, the support plate 123 functions also as a rear cabinet of the display section 111. Each of the thin type batteries 122 is, for example, a lithium polymer battery which has a thickness of 2 mm to 6 mm and a flat-portion area of 10 cm² or more. The control board 124 is, for example, a flexible printed circuit board, and includes an IC (Integrated Circuit) 129 for control use and a power supply line 128.

In the thin type battery section 121, as shown in FIG. 8, flat portions of the four thin type batteries 122, 122, 122, 122 having large-mass are closely contacted with and fixed to the thin, high-strength support plate 123. The slender rectangular control board 124 is also closely contacted with and fixed to the thin, high-strength support plate 123. Therefore, even if the thin type batteries 122 are large in mass and relatively low in strength, the thin type batteries 122 incur no bending deformation since the thin type batteries 122 are fixed in close contact to the high-strength support plate 123. Thus, the thin type batteries 122 are reliably free from damage of electrical connection between the power supply line and the positive terminals 122a or negative terminals 122b of the thin type batteries 122. On the other hand, even though the support plate 123 is extremely thin, the support plate 123 is backed up and reinforced by the thin type batteries 122 and the control board 124 because the flat portions of the thin type batteries 122 and the rear surface of the control board 124 are fixed in close contact to the support plate 123. Thus, the support plate 123, that is, the rear side of the display section 111 is hardly flexed or dented.

Unshown double-faced adhesive tape, presser plate spring or the like may be used so as to fix the support plate 123 and thin type batteries 122. By using these, the thin type batteries 122 are removably fixed to the support plate 123. By using adhesive or the like, however, the thin type batteries 122 may be unremovably fixed to the support plate 123.

The thin type battery section 121 is small in thickness because the support plate 123, the thin type batteries 122 and the control board 124 are all small in thickness. Thereby, the thin type battery section 121 greatly contributes to a thinning of the entire display section 111.

Meanwhile, the control board 124 is placed at a center of a rectangular region slightly inside the outer edge of the support plate 123. Two thin type batteries 122, 122 are placed on each one side of the control board 124 so that outer edges of the thin type batteries 122 extend along edges of the rectangular region. The support plate 123 and the thin type batteries 122 makes the thin type battery section 121 shaped at its edge portion into a stepped form. This stepped portion of the thin type battery section 121 is so formed as to be closely fitted to the stepped fitting portions 132 of the casing 131 shown in FIG. 7. Thereby, reverse-directed insertion for the thin type battery section 121 can be prevented, thus allowing reliable electrical connection between unshown contacts of the casing 131 side and the thin type battery section 121 side.

A semicircular or hemispherical cutout 127 serving as a part of a detent mechanism is formed at a portion in the support plate 123 near the stepped edge portion of the thin type battery section 121. Meanwhile, a ball (not shown) as well as a spring (not shown) for biasing the ball, which serve as another part of the detent mechanism, are provided in the fitting portion 132 of the casing 131. Then, when the thin type battery section 121 is slid along the fitting portions 132 of the casing 131 so as to be fitted to the casing 131, the ball biased by the spring is fitted into the cutout 127. Thus, this engagement of the ball and the cutout 127 makes the thin type battery section 121 held to the casing 131, so that the thin type battery section 121 can be prevented from falling off from the casing 131.

Meanwhile, the positive terminals 122a and the negative terminals 122b of the four thin type batteries 122 are protrudent toward and onto the control board 124 so as to be electrically connected in series or parallel to the power supply line (not shown) on the control board 124. Since the positive terminals 122a and the negative terminals 122b of the two thin type batteries 122 placed on each one side of the control board 124 protrude onto the control board 124 so as to be connected to the power supply line as shown above, the power supply line can be made short in length and the thin type batteries 122 and the control board 124 can be mounted compact on the support plate 123.

Further, overall upper surfaces of the thin type batteries 122, 122, 122, 122 and the control board 124 are coated with the protective film 125 made of resin, so that the thin type batteries 122 and the control board 124 are protected from moisture, dust and the like. However, this protective film 125 may be omitted. FIG. 8 shows part of the protective film 125 in a broken state for explanation's sake.

The thin type battery section 121 composed of the support plate 123, the thin type batteries 122, the control board 124 and the protective film 125 can be traded even by itself as a thin type battery assembly 121. Then, this thin type battery assembly 121 has a high commodity value by virtue of its good appearance, which is based on its surface coating with the support plate 123 and the protective film 125, as well as of its massive feeling based on the large-mass thin type batteries 122.

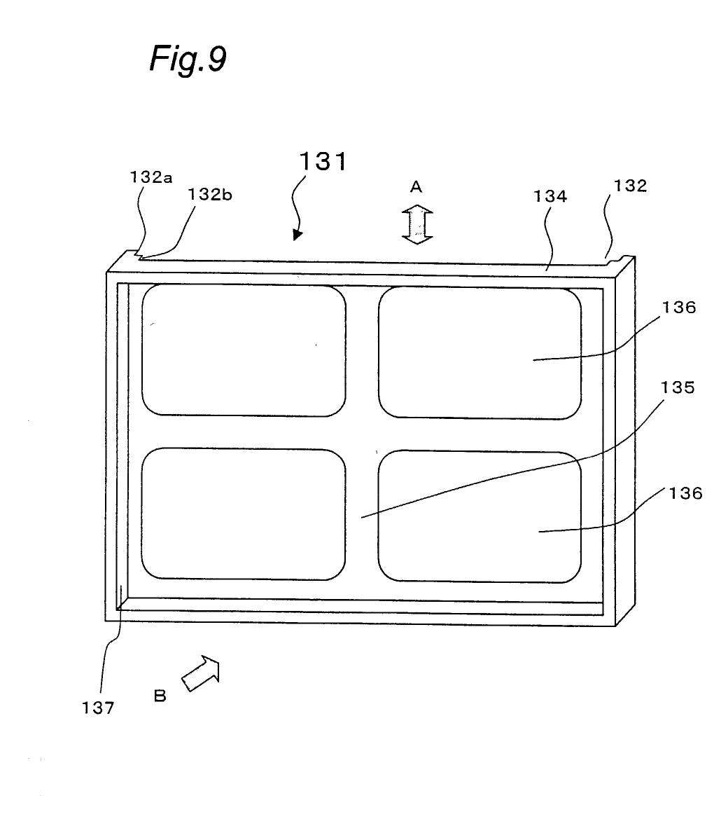

Meanwhile, the casing 131 is a frame structure as shown in FIG. 9, and composed of a rectangular outer frame 134, and a cross-shaped beam portion 135 interconnecting upper-and-lower sides and right-and-left sides of the rectangular outer frame 134. Providing the cross-shaped beam portion 135 in addition to the outer frame 134 in this way ensures a sufficient strength. Specifically, the casing 131, which is reinforced by the cross-shaped beam portion 135, has enough strength to be prevented from deformation when a very large force is applied to the casing 131 upon opening or closing of the casing 131 under the state that the thin type battery section 121 having the high-density, large-weight thin type batteries 122 is set, or when the thin type battery section 121, which serves also as a rear cabinet and which is removable, is removed from the casing 131. Also, the casing 131 has cavity portions 136 formed between the outer frame 134 and the beam portion 135, thus reduced in weight, which in turn reduces the weight of the display section 111. It is noted here that the cross-shaped beam portion 135 may be replaced with a beam portion shaped like “I”, a quarter turn of “I”, “H”, a quarter turn of “H” etc. which are not shown. Further, the beam portion 135 may be replaced by using an “X”-shaped brace, i.e., diagonal stay, or the like.

On the front side of the casing 131, a step portion 137 is formed by the outer frame 134 and the beam portion 135. Thus, the LCD panel 130 shown in FIG. 7 is embedded in this step portion 137 in a direction of B to be fitted. On the other hand, on the rear side of the casing 131, there is formed the fitting portions 132 i.e. stepped recessed portions which extend from the upper side portion of the outer frame 134 downward along right-and-left side portions of the outer frame 134. Thus, the edge portions of the thin type battery section 121 shown in FIGS. 7 and 8 are removably fitted to this fitting portions 132 in a direction of A. The fitting portion 132 is composed of a support-plate fitting portion 132a and a thin-type battery accommodating portion 132b. The support-plate fitting portions 132a are fitted with the edge portions of the support plate 123 of the thin type battery section 121, and the thin-type battery accommodating portions 132b accommodate the thin type batteries 122 and the control board 124.

Material for the casing 131 of the frame structure is provided by a strong lightweight metal such as aluminum, magnesium or titanium, or an alloy of them. To this metallic casing 131 is connected a ground line of the circuit on the control board 124 of the thin type battery section 121 shown in FIG. 8 so that the casing 131 serves for the role of an electromagnetic shield, thus providing measures for electromagnetic wave noise.

Meanwhile, the thin type batteries 122 of the thin type battery section 121 shown in FIG. 8 generates heat when charged or discharged. Also, in the case where the LCD panel 130 shown in FIG. 7 is a transmission LCD panel equipped with a backlight composed of an unshown fluorescent tube, the fluorescent tube generates heat. However, since the casing 131 is made of metal, a large diffusion of heat and a large radiation effect of heat is produced at the display section 111, so that the display section 111 as a whole shows small increase in temperature and uniformity in temperature distribution. Thus, there are no possibilities that the capacity of the thin type batteries 122 may be adversely affected, or that the LCD panel 130 may be deteriorated in display grade because the display section 111 is uniform in temperature distribution and free from locally high temperature portions.

In addition, although not shown in FIG. 9, the hinge 133 shown in FIG. 7 is coupled to the casing 131.

Although the display section 111 is made up by fixing the LCD panel 130 to the casing 131 and further removably attaching the thin type battery section 121 thereto in the above portable information equipment 100, it is also possible to attach a decorative panel, which is not shown, to the casing 131.

In the portable information equipment of the above constitution, now assume that the thin type batteries 122 has run out of its life. Then, the thin type batteries 122 can be easily replaced with another by removing the thin type battery section 121 from the casing 131 since the thin type battery section 121 shown in FIGS. 7 and 8 is removably attached to the casing 131.

More specifically, in the case where the thin type batteries 122 are removably attached to the support plate 123 by means of double-faced adhesive tape, presser plate spring or the like, the thin type battery section 121 is first removed from the casing 131. Next, the protective film 125 and the run-out thin type batteries 122 are removed from the support plate 123. Thereafter, new thin type batteries 122 and protective film 125 are attached to the support plate 123, and the edge portions of the thin type battery section 121 are fitted into the fitting portions 132. Then, the thin type battery section 121 is securely fixed to the casing 131 by the detent mechanism where an unshown ball on the casing 131 side is fitted into the cutout 127 of the thin type battery section 121. In this way, the support plate 123 can be easily reused by replacing only the run-out thin type batteries 122 and protective film 125 with new ones.

Meanwhile, in the case where the thin type batteries 122 are unremovably fixed to the support plate 123 by means of adhesive or the like, the thin type battery section 121 having the run-out thin type batteries 122 is removed from the casing 131. Next, a new thin type battery section 121 having new thin type batteries 122 is fitted into the fitting portion 132 of the casing 131, where the thin type batteries 122 are replaced together with the support plate 123. In this way, the thin type batteries 122 can be replaced with great ease.

When the thin type battery section 121 is fitted to the casing 131, the stepped edge portions of the thin type battery section 121 is fitted to the stepped fitting portions 132 of the casing 131 in a direction along side edges of the casing 131 or in a direction perpendicular to the rear surface of the casing 131 i.e. the rear side of the display section 111 which the support plate 123 forms. Therefore, the thin type battery section 121 is prevented from reverse-directed insertion, so that connection of unshown contacts on the thin type battery section 121 side and the casing 131 side can be securely obtained.

Meanwhile, the thin type battery section 121, which serves for the role of a rear cabinet of the display section 111, is backed up by putting the thin type batteries 122 and the control board 124 into close contact with the thin high-strength support plate 123. Thus, the thin type battery section 121 has sufficient strength, which ensures a strength of the display section 111. More specifically, the flat portion of the large-mass thin type batteries 122 and the rear side of the control board 124 are fixed in close contact to the high-strength support plate 123. Therefore, the support plate 123, even though extremely thin, is backed up and reinforced by the thin type batteries 122 and the control board 124, so that the support plate 123, that is, the rear side of the display section 111 hardly flexes or dents. Also, the flat portions of the thin type batteries 122 are fixed in close contact to the high-strength support plate 123. Therefore, the thin type batteries 122, even though relatively low in strength, incur no bending deformation or the like, so that the thin type batteries 122 is free from the possibility of damaging the reliability of electrical connection between the power supply line and the positive terminals 122a and negative terminals 122b of the thin type batteries 122.

Further, the casing 131 is a frame structure in which upper-and-lower sides and right-and-left sides of the rectangular outer frame 134 are connected together, respectively, by means of the cross-shaped beam portion 135 as shown in FIG. 9. Therefore, the casing 131 has enough strength to be prevented from deformation even when a very large force is applied to the casing 131 upon opening or closing of the casing 131 in the state that the thin type battery section 121 having the high-density, large-weight thin type batteries 122 is set, or even when the thin type battery section 121, which serves also as a rear cabinet and which is removable, is removed from the casing 131. Therefore, the display section 111 suffices in strength even if it is opened and closed with the large-mass thin type batteries 122 set, and even if the thin type battery section 121 is removable from the casing 131.

Still further, the support plate 123, the thin type batteries 122 and the control board 124 are all small in thickness. Consequently, the thin type battery section 121 is small in thickness, and therefore, the display section 111 as a whole is small in thickness.

Accordingly, in the portable information equipment of this embodiment, the thin type batteries 122 can be replaced easily without impairing the strength of the thin display section 111.

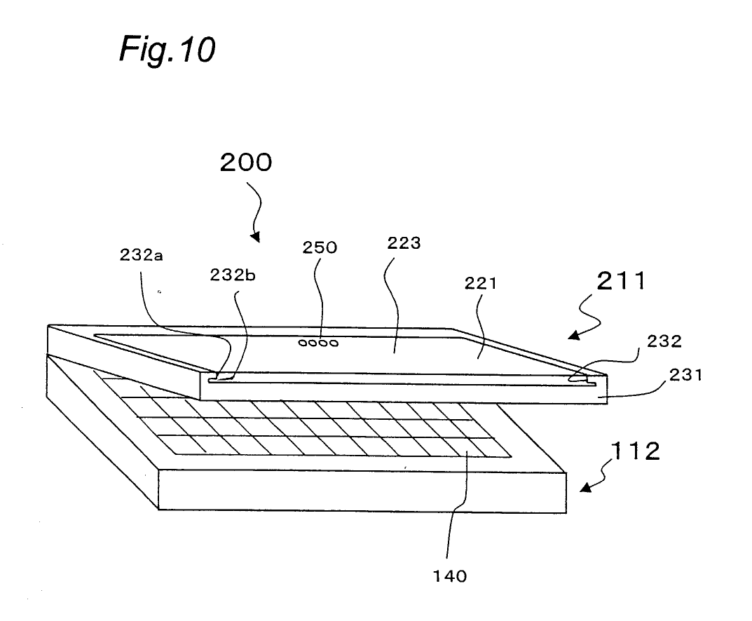

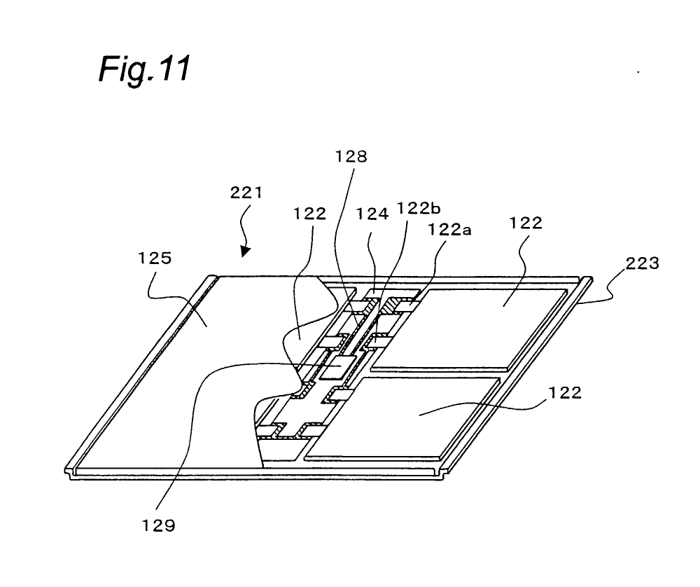

FIG. 10 is a perspective view showing portable information equipment as a portable electronic equipment according to another embodiment of the present invention. FIG. 10 illustrates a state in which a display section 211 is closed halfway. FIG. 11 is a perspective view of a thin type battery section 221 of the portable information equipment. Referring to FIG. 10, a fitting portion 232 of a casing 231 of the display section 211, an outer edge portion of the thin type battery section 221 to be fitted to the fitting portion 232, the configuration of a support plate 223, and a remainder indicator 250 are solely different from the constituent members of the embodiment shown in FIGS. 7, 8 and 9. The rest of the constitution is the absolutely same as constituent members of the embodiment shown in FIGS. 7, 8 and 9. Accordingly, hereinbelow, only the differences from the embodiment shown in FIGS. 7, 8 and 9 are described in detail, and the same constituent members as those of the embodiment shown in FIGS. 7, 8 and 9 are designated by the same reference numerals and their description is omitted.

As shown in FIG. 10, on the rear side of the casing 231 of the display section 211 is provided a fitting portion 232 composed of a portion 232a opening toward the rear side of the casing 231 and a guide groove 232b adjoining the portion 232a. Ends of a pair of opposing stepped outer edge portions of the support plate 223 of the thin type battery section 221 are fitted to the guide groove 232b of this fitting portion 232 so that the thin type battery section 221 is removably attached to the fitting portion 232 of the casing 231. Thereby, the thin type batteries 221 are easily replaced. The thin type battery section 221 is permitted to slide only unidirectionally along the guide groove 232b. Therefore, the thin type battery section 221 can be attached to a desired position simply and reliably, and moreover prevented from drops. Further, electrical connection between terminals, which are not shown, can be achieved reliably.

The support plate 223 has a recessed portion on its front face side as shown in FIG. 11. Flat portions of the thin type batteries 122 and a bottom face of the control board 124 are fitted in close contact to the bottom face of the recessed portion, in the absolutely same fashion as in the arrangement shown in FIG. 8.

Also, a remainder indicator 250 which shows the remaining level of the thin type batteries of the thin type battery section 221 is provided on the rear side of the display section 211, i.e. the rear side of the support plate 223. For this remainder indicator 250, a sheet light-emitter, an LED (Light-Emitting Diode) chip or the like is desirably used. The LED chip, for example, may be bonded directly onto the control board. In addition, when another battery is included in the body section 112, the remainder indicator 250 may be arranged so as to indicate a total remaining level of capacity of the above battery and the thin type batteries of the thin type battery section 221.

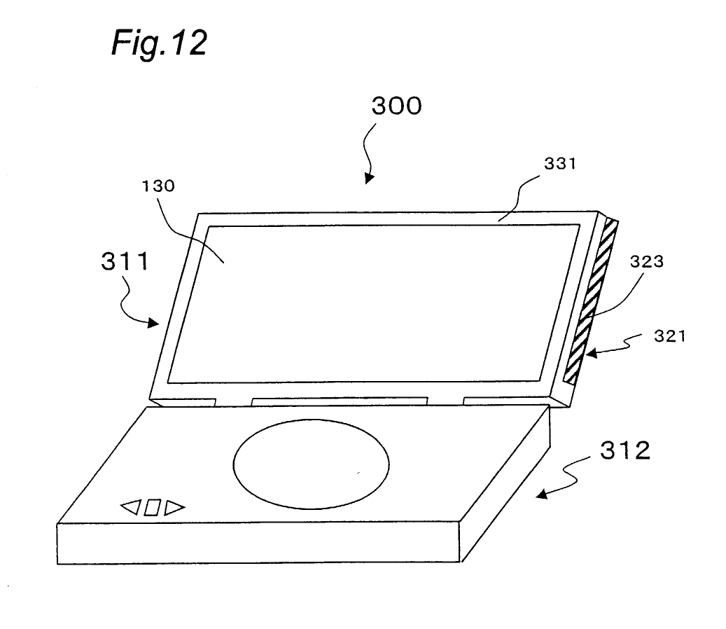

FIG. 12 shows personal DVD equipment 300 as an example of the portable electronic equipment according to another embodiment of the present invention.

In this personal DVD equipment 300, a display section 311 is openably and closably fitted to a body portion 312 having an operating section, a storage section and a control section. In this display section 311, an LCD panel 130 is attached on the front face side of a casing 331, and a thin type battery section 321 is removably attached on the rear face side, thereby facilitating the replacement of unshown thin type batteries.

The display section 311 differs from the display section 211 of the embodiment shown in FIG. 10 only in the structure that the thin type battery section 321 is fitted to the casing 331. Therefore, only this difference point is described below. An outer edge portion of a support plate 323 of the thin type battery section 321 is not stepped. An unshown longitudinal dovetail is provided at the outer edge portion of the support plate 323 while a dovetail groove to be fitted with the dovetail is provided in the casing 331. By dovetail coupling, the thin type battery section 321 is removably fitted to the casing 331.

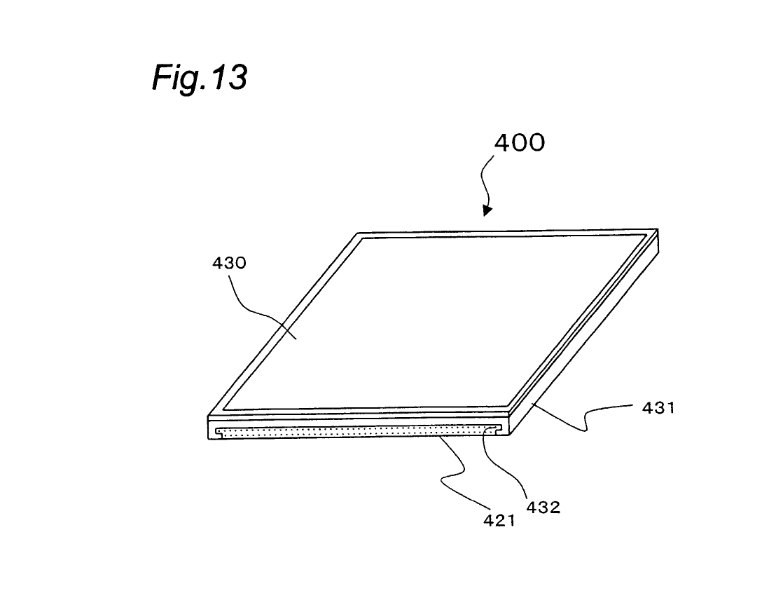

FIG. 13 shows a system integrated device 400 as an example of the portable electronic equipment according to another embodiment of the present invention.

The system integrated device 400 is made up of a system integrated display 430 having mainly display function and information processing function, a casing 431 for accommodating therein the system integrated display 430, and a thin type battery section 421 for supplying electric power to the system integrated display 430.

The system integrated display 430 is a flat display device which has an area generally equal to that of the display screen and which is a device having an information processing function by a microcomputer or other system IC (Integrated Circuit) being mounted on, for example, a glass substrate.

The system integrated display 430 is fabricated, for example, by laser annealing of an amorphous silicon TFT (thin film transistor) which has conventionally been used for TFT LCD devices so as to implement poly-crystallization and high-speed operation of the TFT, and by forming also peripheral circuits including a control circuit on a glass substrate. Otherwise, the system integrated display 430 is so constructed that a silicon chip including a control IC is mounted directly on a glass substrate constituting the flat display device (COG: Chip On Glass).

This system integrated display 430 is accommodated and thereby protected in a casing, i.e. frame 431. Thus, a strength as a portable electronic equipment is secured for the system integrated device 400.

The casing 431 has a fitting portion 432 in the same form as the fitting portion 232 of the casing 231 of FIG. 10. The thin type battery section 421 in the same form as the thin type battery section 221 of FIG. 10 is removably fitted to the fitting portion 432.

As shown above, since the thin type battery section 421 is removably fitted to the casing 431, replacement of the thin type batteries can be achieved easily.

Further, the thin type battery section 421, by virtue of having an area generally equal to that of the system integrated display 430, allows large-area or multiple thin type batteries to be mounted thereon and has a large electrical capacity. Therefore, the system integrated device 400 can be used over a prolonged period without replacement of batteries.

The above system integrated device 400 is card-type or sheet-type portable information equipment or portable AV equipment.

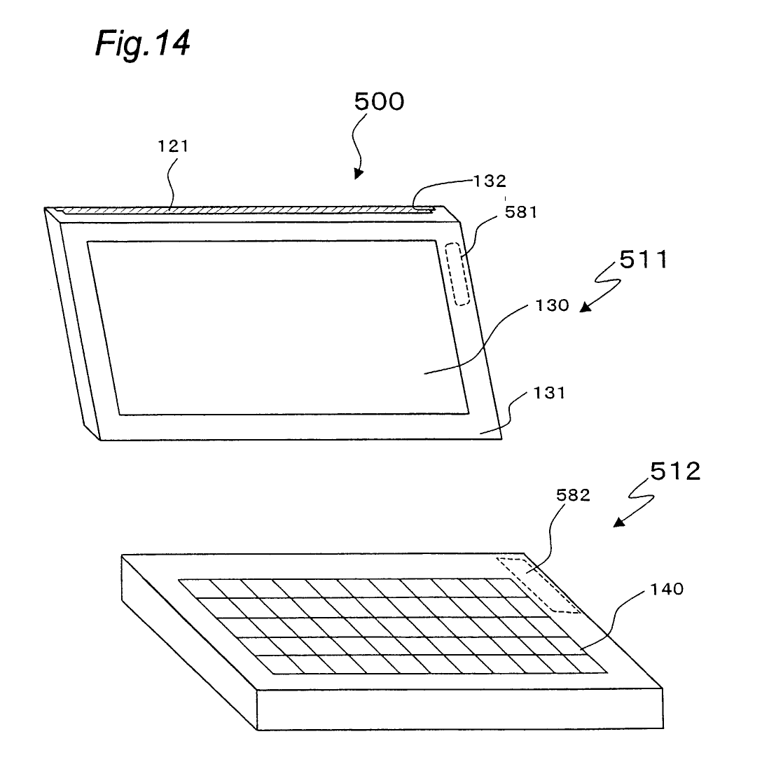

FIG. 14 is a perspective view showing portable electronic equipment according to another embodiment of the present invention. This portable electronic equipment 500 differs from the portable electronic equipment of the embodiment shown in FIGS. 7, 8 and 9 only in that a display section 511 and a body section 512 are provided separately and independently from each other, and that radio transmitting/receiving sections 581, 582 are provided in the display section 511 and the body section 512, respectively. Accordingly, hereinbelow, only the differences from the embodiment shown in FIGS. 7, 8 and 9 are described in detail. The same constituent members as those of the embodiment shown in FIGS. 7, 8 and 9 are designated by the same reference numerals and their description is omitted.

A display signal for displaying an image on the LCD panel 130 is transmitted wirelessly from the radio transmitting/receiving section 582 of the body section 512 to the radio transmitting/receiving section 581 of the display section 511, while a control signal for instructing an operation of the body section 512 is transmitted wirelessly from the radio transmitting/receiving section 581 of the display section 511 to the radio transmitting/receiving section 582 of the body section 512.

Radio waves, infrared rays or ultrasonic waves, typified by Bluetooth, are used as the medium for the radio transmission.

With this arrangement, the display section 511 and the body section 512 have radio transmitting/receiving sections 581, 582, and the display section 511 is supplied with electric power from the thin type battery section 121. Therefore, the display section 511 can be separated from the body section 512 and used away from the body section 512.

Also, for the radio transmitting/receiving section 581 of the display section 511, the metallic casing, i.e., frame structure 131 explained in detail in FIG. 9 can be used as an antenna or a part thereof.

The body section 512 is not limited to the body section of portable information equipment such as notebook personal computers shown in FIG. 7 or the body section of personal DVD devices such as shown in FIG. 12. Inserted, the body section 512 may be, for example, a set-top box or game machine.

In the above embodiment, the display section 511 and the body section 512 are provided with the radio transmitting/receiving sections 581, 582, respectively. It is also possible, however, to provide a radio receiving section in the display section and a radio transmitting section in the body section so that a signal is transmitted wirelessly only from the body section to the display section.

As apparent from the foregoing description, according to the portable electronic equipment of the present invention, the thin type battery section having flat thin type batteries that supply electric power to the flat display panel is removably fitted to the casing of the display section so as to be positioned on the rear face side of the flat display panel. Thus, the thin type battery section and the casing help enhance the strength of the display section, and moreover the thin type batteries can be easily replaced.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

What is claimed is:

1. Portable electronic equipment having a display section comprising:
a casing;
a flat display panel mounted on the casing; and
a thin type battery section having a flat thin type battery and removably fitted to the casing so as to be positioned on a rear face side of the flat display panel.

2. The portable electronic equipment according to claim 1, wherein
the thin type battery section has a support plate forming the rear face of the display section, and wherein
the thin type battery is fitted to the support plate.

3. The portable electronic equipment according to claim 2, wherein
the support plate is generally rectangular shaped, and wherein
a flat portion of the thin type battery and a control board having a circuit for control use are fitted in close contact to the support plate so as to occupy a generally rectangular region inner than an outer edge of the support plate.

4. The portable electronic equipment according to claim 3, wherein
a singularity or plurality of the thin type batteries are disposed on each one side of the control board, and wherein
positive terminals and negative terminals of the individual thin type batteries are protrudent toward the control board and connected to a power supply line provided on the control board.

5. The portable electronic equipment according to claim 2, wherein
a singularity or plurality of the thin type batteries are attached to the support plate so that an edge portion of the thin type battery section is formed into a step-like shape by the support plate and the thin type batteries, and wherein
the casing has a fitting portion to which the edge portion of the thin type battery section is to be removably fitted, and the fitting portion comprises a support-plate fitting portion to which the edge portion of the support plate is fitted, and a thin-type battery accommodating portion for accommodating the thin type batteries.

6. The portable electronic equipment according to claim 2, wherein
the support plate is generally rectangular shaped with at least a pair of its opposing edge portions formed into a step-like shape, and has a recess at a center portion of the support plate, and the thin type battery is attached to the recess with the flat portion of the thin type battery in close contact therewith, and wherein
the casing has a fitting portion to which a top of the edge portion of the support plate is removably fitted.

7. The portable electronic equipment according to claim 6, wherein
the fitting portion has a guide groove for allowing the support plate forming the rear face of the display section to slide along the rear face.

8. The portable electronic equipment according to claim 1, wherein
the casing is a frame structure having an outer frame and at least one of a beam portion and a brace coupled to the outer frame.

9. The portable electronic equipment according to claim 1, further comprising:
a body section including an input section and a control section having an information processing function,
wherein the display section includes a radio receiving section while the body section includes a radio transmitting section, and
wherein the radio receiving section of the display section receives data transmitted by radio from the radio transmitting section of the body section so as to display the data on the flat display panel.

10. The portable electronic equipment according to claim 1, wherein
the flat display panel serves also as an input section, a control section having an information processing function is provided in the casing, and the flat display panel and the thin type battery section are generally equal in area to each other.

11. A thin type battery assembly comprising:
a support plate; and
a singularity or plurality of thin type batteries attached to the support plate so as to be positioned in a region which is inner by a specified size than an outer edge of the support plate,
wherein the edge portion of the support plate and the thin type batteries form a step-like shape.

12. A thin type battery assembly comprising:
a generally rectangular-shaped support plate of which at least a pair of opposing edge portions are formed into a step-like shape, and which has a recess at a center portion; and
a thin type battery attached to the recess of the support plate with its flat portion in close contact therewith.

13. The thin type battery assembly according to claim 11, wherein
a control board having a circuit for control use is attached to the support plate, and a singularity or plurality of the thin type batteries are disposed on each one side of the control board, and wherein
a positive terminal and a negative terminal of each of the thin type batteries are protrudent toward the control board and connected to a power supply line provided on the control board.

14. The thin type battery assembly according to claim 12, wherein
a control board having a circuit for control use is attached to the support plate, and a singularity or plurality of the thin type batteries are disposed on each one side of the control board, and wherein
a positive terminal and a negative terminal of each of the thin type batteries are protrudent toward the control board and connected to a power supply line provided on the control board.
